(19) United States
(12) Patent Application Publication
(10) Pub. No.: US 2026/0332099 A1
(43) Pub. Date: Oct. 22, 2026

(54) POWER AMPLIFIER

(71) Applicant: Mitsubishi Electric Corporation, Tokyo (JP)

(72) Inventors: Kazuya YAMAMOTO, Tokyo (JP); Miyo MIYASHITA, Tokyo (JP); Katsuya KATO, Tokyo (JP)

(73) Assignee: Mitsubishi Electric Corporation, Tokyo (JP)

(21) Appl. No.: 18/994,807

(22) PCT Filed: Nov. 10, 2022
(86) PCT No.: PCT/JP2022/041857

§ 371 Date: Jan. 15, 2025

(51) Int. Cl. H03F 1/02; H03F 3/21; H03F 3/45

(52) U.S. Cl. CPC H03F 1/0216; H03F 3/21; H03F 3/45183; H03F 2200/213

(57) ABSTRACT

A power amplifier includes a stacked circuit (19) including n (n is integer of 2 or more) FETs, wherein, when the FETs numbered from 1 to n and i is an integer of 2 or more and (n−1) or less, a first FET (12) includes a gate terminal receiving an input signal, a drain terminal connected to a source terminal of a second FET, and a source terminal connected to GND, an i-th FET includes a drain terminal connected to a source terminal of an (i+1)-th FET, and an n-th FET (18) includes a drain terminal outputting an output signal and connected to a power supply; resistors connected to gate terminals of the second to n-th FETs; capacitors connected to electrodes on sides opposite to the gate terminals of the respective resistors; and first switches connected in parallel with the respective resistors.

### FIELD

The present disclosure relates to a stacked power amplifier.

### BACKGROUND

As a power amplifier for a mobile terminal, a power amplifier using a GaAs HBT (Heterojunction Bipolar Transistor) is currently mainly used. The reasons are that, for example: it is operable with a single power supply in a normally-off state; it is operable with a Li-ion battery voltage of 3.7 V, and a chip area is small when incorporated in an integrated circuit because power density is high as compared with a GaAs FET (Field Effect Transistor) within an output power range up to about several W; and an extremely high yield can be realized as compared with the GaAs FET.

In recent years, however, to facilitate control in the terminal, a CMOS (Complementary Metal-Oxide-Semiconductor) control circuit that enables digital control is mounted on a power amplifier, a band selector switch, and an antenna switch, separately from the GaAs HBT. Further, from a background that a GaAs HBT chip, which is not Si-based, cannot be integrated with the control circuit and leads to an increase in costs during mass production as compared with a CMOS chip, there has been a strong desire for a CMOS-based power amplifier.

A standard voltage of a CMOS FET is 1.2 V in a 65-nm process and is 1.8 V in a 0.18-μm process, and is significantly lower than a battery voltage (3.7 V). Thus, the power amplifier including a single-stage CMOS FET cannot be used.

Under such a background, a stacked power amplifier useful for operating the CMOS as the power amplifier with a power supply voltage as high as possible has attracted attention (for example, see NPL 1).

### CITATION LIST

### Patent Literature

[NPL 1] S. Pornpromlikit, et al., A Watt-Level Stacked-FET Linear Power Amplifier in Silicon-on-Insulator CMOS, IEEE Transactions on Microwave Theory and Techniques, vol. 58, no. 1, pp. 57-64, January 2010.

### SUMMARY

### Technical Problem

Next, problems will be described taking, as an example, a four-stage stacked power amplifier, in which FETs each have standard voltage of 1.2 V and which is fabricated by using the 65-nm CMOS process. In a case of the example, assuming that the amplification FETs evenly operate, the stacked power amplifier can operate at the power supply voltage of up to 4.8 V. Then, assume that, while a standard voltage of a Li-ion battery is 3.7 V, the voltage is boosted to 4.8 V by a DC/DC converter for high output power operation, and operation is performed with output power of 1 W.

In mobile telecommunications, output power of the terminal is often reduced based on a distance between a base station and the terminal. In other words, the output power is switched to a maximum output power when the distance is large, and the output power is switched to low output power when the distance is small. Such switching is frequently performed. For example, in urban areas, the distance between the base station and the terminal is relatively small. Thus, the output power of the terminal is often reduced to about several m W to about several tens mW. Control of the output power is achieved by reducing the power supply voltage of the power amplifier. This is because, when the input power is reduced and the output power is reduced while the power supply voltage remains high, efficiency of the power amplifier is significantly lowered.

However, when the power supply voltage of the stacked power amplifier is reduced from 4.8 V to, for example, 2.4 V, only the power supply voltage is reduced while load lines of the FETs remain the same. As a result, the load lines of the FETs in the respective stages are far from optimum, which leads to a problem of not only a reduction in the output power but also a significant reduction in efficiency.

An object of the present disclosure, which has been made to solve the above-described problems, is to provide a power amplifier that can suppress lowering in efficiency even when a power supply voltage is reduced.

### Solution to Problem

A power amplifier according to the disclosure includes a stacked circuit including n (n is integer of 2 or more) FETs, wherein, when the FETs numbered from 1 to n and i is an integer of 2 or more and (n−1) or less, a first FET includes a gate terminal receiving an input signal, a drain terminal connected to a source terminal of a second FET, and a source terminal connected to GND, an i-th FET includes a drain terminal connected to a source terminal of an (i+1)-th FET, and an n-th FET includes a drain terminal outputting an output signal and connected to a power supply; resistors connected to gate terminals of the second to n-th FETs of the stacked circuit; capacitors connected to electrodes on sides opposite to the gate terminals of the respective resistors; and first switches connected in parallel with the respective resistors.

### Advantageous Effects of Invention

According to the present disclosure, it is possible to provide the power amplifier that can suppress lowering in efficiency even when the power supply voltage is reduced.

### BRIEF DESCRIPTION OF DRAWINGS

FIG. 1 illustrates a circuit configuration of a power amplifier according to Embodiment 1.

FIG. 2 is a diagram showing a load line of a FET of the power amplifier according to Embodiment 1.

FIG. 3 is a diagram showing a load line of a FET of the power amplifier according to Embodiment 1.

FIG. 4 illustrates a circuit configuration of a power amplifier according to Embodiment 2.

FIG. 5 illustrates a circuit configuration of a power amplifier according to Embodiment 3.

### DESCRIPTION OF EMBODIMENTS

### Embodiment 1

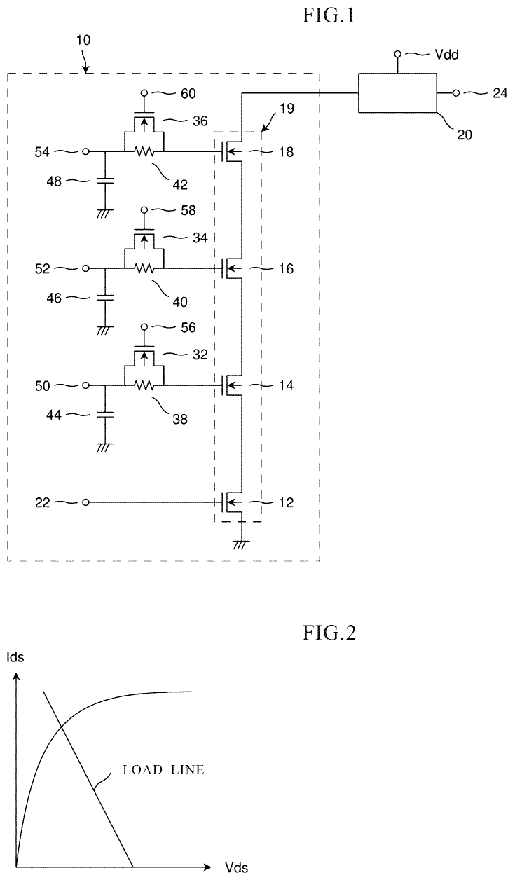

FIG. 1 illustrates a circuit configuration of a power amplifier 10 according to Embodiment 1. The power amplifier 10 is manufactured using a 65-nm CMOS process, and a maximum standard voltage of an FET is 1.2 V. The maximum standard voltage indicates a maximum direct-current voltage that is applicable between a drain terminal and a source terminal of an FET having the shortest gate length used in the CMOS process and can achieve long-term reliability of the FET.

An FET 12 includes a gate terminal receiving an input signal from an input terminal 22, a drain terminal connected to a source terminal of an FET 14, and a source terminal connected to GND. The FET 14 includes a drain terminal connected to a source terminal of an FET 16. The FET 16 includes a drain terminal connected to a source terminal of an FET 18. The FET 18 includes a drain terminal that outputs an output signal and is connected to a power supply (Vdd). A circuit including the four FETs is referred to as a stacked circuit 19. Each of the FET 12, the FET 14, the FET 16, and the FET 18 is an n-type FET. Although not illustrated, an input matching circuit is connected to the input terminal 22. An output matching circuit 20 is connected between an output terminal 24 and the drain terminal of the third FET 18.

A bias terminal 50, a bias terminal 52, and a bias terminal 54 are gate bias terminals of the FET 14, the FET 16, and the FET 18, and are connected to gate terminals of the FET 14, the FET 16, and the FET 18 through a resistor 38, a resistor 40, and a resistor 42 each having a resistance value of about kΩ, respectively. An FET switch 32, an FET switch 34, and an FET switch 36 are connected respectively in parallel with the resistor 38, the resistor 40, and the resistor 42. These FET switches function as switches for bypassing the respective resistors. The FET switch 32, the FET switch 34, and the FET switch 36 are respectively turned on/off by a switch terminal 56, a switch terminal 58, and a switch terminal 60.

The bias terminal 50, the bias terminal 52, and the bias terminal 54 are terminals on sides opposite to the gate terminals of the resistor 38, the resistor 40, and the resistor 42, respectively. A capacitor 44, a capacitor 46, and a capacitor 48 are connected between the GND and the respective bias terminals. The capacitor 44, the capacitor 46, and the capacitor 48 are variable capacitors.

The number of FETs included in the stacked circuit is not limited to four. Here, description is given while the number of FETs included in the stacked circuit is n (n is number of 2 or more). The FETs are numbered from 1 to n, and i is an integer of 2 or more and (n−1) or less. A first FET corresponds to the FET 12 illustrated in FIG. 1, and includes a gate terminal receiving an input signal, a drain terminal connected to a source terminal of a second FET, and a source terminal connected to GND. An i-th FET corresponds to each of the FET 14 and the FET 16 illustrated in FIG. 1, and includes a drain terminal connected to a source terminal of an (i+1)-th FET. An n-th FET corresponds to the FET 18 illustrated in FIG. 1, and includes a drain terminal that outputs an output signal and is connected to a power supply (Vdd).

Referring back to the case where the number of FETs included in the stacked circuit is four, description is continued. Since the maximum standard voltage of each of the FETs is 1.2 V, a power supply voltage of the power amplifier 10 can be raised up to a direct-current voltage of 4.8 V. A well of each of the FETs is separated, and a back gate is connected to a source. In a case where each of the FETs is a fully-depleted SOI (Silicon On Insulator), the back gate may be in a floating state. The control FETs such as the FET switch 32, the FET switch 34, and the FET switch 36 are required to have a withstand voltage of up to 4.8 V. Therefore, an FET having a thick gate oxide film and a high withstand voltage is used as each of the control FETs.

In a case where the power supply voltage is 4.8 V that is the maximum voltage, a voltage of 4.8 V is applied to the drain terminal of the FET 18 when a voltage drop does not occur. When a voltage drop occurs, the applied voltage is accordingly reduced. In this example, description is given based on an assumption that a voltage drop does not occur. In a case where the power supply voltage is 4.8 V, the FET switch 32, the FET switch 34, and the FET switch 36 are all closed to bypass the resistor 38, the resistor 40, and the resistor 42, respectively. As a result, a voltage of 1.2 V is applied between the drain terminal and the source terminal of each of the FET 12, the FET 14, the FET 16, and the FET 18, and all of these FETs perform amplification operation.

Next, a case where the power supply voltage is reduced to 3.6 V is considered. In this case, the FET switch 32 and the FET switch 34 are closed, and the FET switch 36 is opened. Therefore, the resistor 42 is enabled, and the FET 18 operates in a switch mode. The switch mode indicates an operation state where the gate terminal of the FET is put into a floating state by the resistor, and accordingly, an input to the source terminal is output from the drain terminal substantially without loss. The remaining FET 12, FET 14, and FET 16 perform the amplification operation. As a result, voltage drop between the drain terminal and the source terminal of the FET 18 is minimized, and the voltage of about 1.2 V is applied between the drain terminal and the source terminal of each of the FET 12, the FET 14, and the FET 16 performing the amplification operation, which makes it possible to realize an optimum state for the power amplification operation. In other words, the FETs operate in a saturation region so as to sufficiently increase a voltage amplitude and a current amplitude during the amplification.

Next, a case where the power supply voltage is reduced to 2.4 V is considered. In this case, the FET switch 32 is closed, and the FET switch 34 and the FET switch 36 are opened. Therefore, the resistor 40 and the resistor 42 connected to the gate terminals of the FET 16 and the FET 18 are enabled, and the FET 16 and the FET 18 operate in the switch mode. The remaining FET 12 and FET 14 perform the amplification operation. As a result, voltage drop between the drain terminal and the source terminal of each of the FET 16 and the FET 18 is minimized, the voltage of about 1.2 V is applied between the drain terminal and the source terminal of each of the FET 12 and the FET 14 performing the amplification operation, which is enough for satisfactory amplification operation.

Next, a case where the power supply voltage is reduced to 1.2 V is considered. In this case, the FET switch 32, the FET switch 34, and the FET switch 36 are all opened. Therefore, the resistor 38, the resistor 40, the resistor 42 connected to the gate terminals of the FET 14, the FET 16, and the FET 18 are enabled, and the FET 14, the FET 16, and the FET 18 operate in the switch mode. The remaining FET 12 performs the amplification operation. As a result, voltage drop between the drain terminal and the source terminal of each of the FET 14, the FET 16, and the FET 18 is minimized, the voltage of about 1.2 V is applied between the drain terminal and the source terminal of the FET 12 performing the amplification operation, which is enough for satisfactory amplification operation.

Note that the order of opening the FET switches in the case where the power supply voltage is reduced is not limited to the above-described order from the FET switch 36 on an upper stage.

The above description is generalized. It is assumed that the number of FETs included in the stacked circuit is n (n is integer of 2 or more), and the FETs are numbered as described above. It is assumed that each of these FETs has the maximum standard voltage of Vm, the voltage applied to the drain terminal of the n-th FET is Vd, and j is an integer of 1 or more and n or less. In a case where (j−1)×Vm<Vdd≤j×Vm is satisfied, (j−1) FET switches among the FET switches are closed and the remaining FET switches are opened.

Even when the power supply voltage is reduced in the above-described manner, the FET switch 32, the FET switch 34, and the FET switch 36 are appropriately opened based on the reduction level of the power supply voltage, which makes it possible to apply, between the drain terminal and the source terminal of each of the FETs performing the amplification operation, the voltage sufficient to operate each of the FETs in the saturation region.

The capacitance values of the capacitors may be set such that load lines of the FET 12, the FET 14, the FET 16, and the FET 18 are equal to one another. FIG. 2 schematically illustrates a load line in the case where all of the FETs perform the amplification operation. To make the load lines of the FETs equal to one another, when input impedance of each of the FET 14, the FET 16, and the FET 18 is Zi (i=1, 2, 3), and an optimum load resistance of a single-stage FET is Ropt, Z1=Ropt, Z2=2×Ropt, and Z3=3×Ropt are preferably established. 4×Ropt is made equal to load impedance as viewed from the drain terminal of the FET 18. For example, when impedance of the output matching circuit 20 is 50Ω, Ropt is 12.5Ω. In this case, the load lines of the FET 12, the FET 14, the FET 16, and the FET 18 are equal to one another.

To set the input impedance Zi (i=1, 2, 3) to the above-described value, the capacitance values of the capacitor 44, the capacitor 46, and the capacitor 48 are set to predetermined values by using an expression 1 (see NPL 1).

$$Zi \approx ( 1 + \frac{C g s}{C i} ) \cdot \frac{1}{g m} \qquad [ Math . 1 ]$$

In the expression, Cgs is a gate-source capacitance of each of the FET 14, the FET 16, and the FET 18, Ci (i=1, 2, 3) is the capacitance value of each of the capacitor 44, the capacitor 46, and the capacitor 48, and gm is a mutual conductance of each of the FET 14, the FET 16, and the FET 18. Note that, in this example, the mutual conductance and the gate-source capacitance are equal among the FET 14, the FET 16, and the FET 18, and an operation frequency is sufficiently lower than a cutoff frequency of each of the FETs.

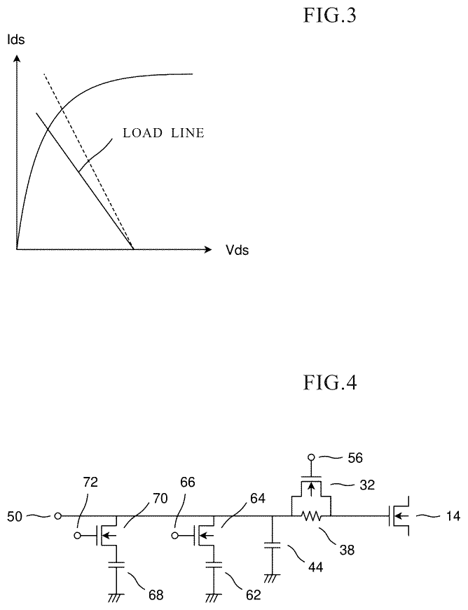

In the case where the power supply voltage is reduced, the load line of each of the FETs is changed as it is. For example, it is assumed that the power supply voltage is reduced to 3.6 V, and the FET switch 36 is opened to operate the FET 18 in the switch mode. In this case, the input impedance Z3 of the FET 18 is 4×Ropt. As a result, the load line of the FET 18 is shifted from the optimum load line illustrated by a dashed line, as illustrated in FIG. 3.

To reduce change of the load line, the capacitance values of the variable capacitances of the capacitor 44 and the capacitor 46 are preferably changed. More specifically, the capacitance value C1 of the capacitor 44 is set so as to satisfy Z1=⅓×4×Ropt, and the capacitance value C2 of the capacitor 46 is set so as to satisfy Z2=⅔×4×Ropt. This makes it possible to suppress change of the load line of each of the FET 12, the FET 14, and the FET 16.

Likewise, in the case where the power supply voltage is reduced to 2.4 V, and the FET switch 34 and the FET switch 36 are opened to operate the FET 16 and the FET 18 in the switch mode, the capacitance value C1 of the capacitor 44 is set so as to satisfy Z1=½×4×Ropt.

The above description is generalized. It is assumed that the number of FETs included in the stacked circuit is n (n is integer of 2 or more), and the FETs are numbered as described above. It is assumed that load impedance as viewed from the drain terminal of the n-th FET is Z0. It is assumed that the number of FETs performing the amplification operation among the second to n-th FETs is m, and the FETs performing the amplification operation are numbered from 1 to m in an ascending order of the FET number in the stacked circuit. When k is an integer of 1 or more and m or less, it is sufficient that the input impedance as viewed from the source terminal of a k-th FET performing the amplification operation is set within a range from (k−0.5)/(m+1)×Z0 to (k+0.5)/(m+1)×Z0. Although the input impedance is ideally set to k/(m+1)×Z0, the input impedance may have the above-described range.

Even when the power supply voltage is reduced in the above-described manner, the load lines of the FETs performing the amplification operation can be made equal to one another by appropriately setting the input impedance of each of the FETs.

As described above, according to the present embodiment, even in the case where the power supply voltage is reduced, it is possible to apply, between the drain terminal and the source terminal of each of the FETs performing the amplification operation, the voltage sufficient to operate each of the FETs in the saturation region. Therefore, lowering in efficiency of the power amplifier can be suppressed.

Further, even in the case where the power supply voltage is reduced, the load lines of the FETs performing the amplification operation can be made equal to one another. Therefore, lowering in efficiency of the power amplifier can be suppressed.

Since switching by the FET switches is adopted, an additional path like a high-frequency bypass circuit is unnecessary at a portion where a high-frequency signal is transmitted. This makes it possible to reduce a circuit area.

### Embodiment 2

In a power amplifier according to Embodiment 2, an additional capacitor, connection of which can be turned on/off by an FET switch is added in addition to the capacitor 44, the capacitor 46, and the capacitor 48 of the power amplifier 10 according to Embodiment 1.

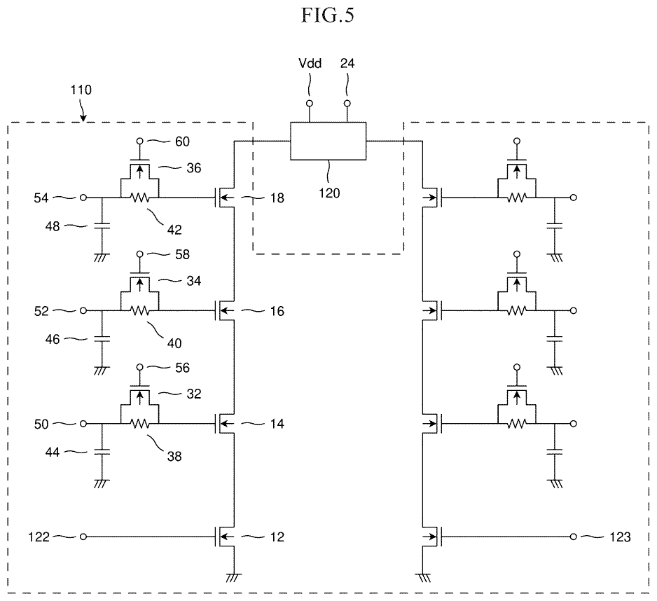

Description is given with reference to FIG. 4 that illustrates only a vicinity of the gate terminal of the FET 14. As illustrated in FIG. 4, in addition to the capacitor 44, an FET switch 64 and an additional capacitor 62, and an FET switch 70 and an additional capacitor 68 are added. The additional capacitor 62 can be turned on/off by the FET switch 64. The additional capacitor 68 can be turned on/off by the FET switch 70.

As with the power amplifier 10 according to Embodiment 1, the power amplifier according to the present embodiment also includes four FETs relating to amplification. Therefore, as understood from the description in Embodiment 1, the capacitance value of the capacitor connected to the gate terminal of the FET 14 is preferably set to any of three values. In the present embodiment, the three capacitance values are switchable by turning on/off the FET switch 64 and the FET switch 70.

Note that the above description is applicable not only to the FET 14 but also to the FET 16 and the FET 18.

Accordingly, in the present embodiment, the capacitance values can be switched in a digital manner by using the normal FETs. Therefore, as compared with a capacitor variable in an analog manner, control is easy and a circuit area can be reduced.

### Embodiment 3

As illustrated in FIG. 5, in a power amplifier 110 according to Embodiment 3, the circuit configuration of the power amplifier 10 according to Embodiment 1 is differentiated. Accordingly, an input signal is a differential signal, and the differential signal is input to an input terminal 122 and an input terminal 123. Differentiation makes it possible to largely suppress influence of gain reduction caused by GND inductance that is a frequent problem in a single-phase amplifier mounted on an Si-based LSI. Alternatively, the power amplifier according to Embodiment 2 may be differentiated.

In the power amplifier according to each of the embodiments, a GaAs FET, an InP FET, or the like can be used in place of the CMOS FET. In a case where a GaAs FET or an InP FET is used, the back gate is normally in a floating state.

### REFERENCE SIGNS LIST

12,14,16,18 FET, 38,40,42 resistor, 44,46,48 capacitor, 32,34,36,64,70 FET switch, 20 output matching circuit, 62,68 additional capacitor, 19 stacked circuit

1. A power amplifier, comprising:
a stacked circuit including n FETs, n is integer of 2 or more wherein, when the FETs numbered from 1 to n and i is an integer of 2 or more and (n−1) or less, a first FET includes a gate terminal receiving an input signal, a drain terminal connected to a source terminal of a second FET, and a source terminal connected to GND, an i-th FET includes a drain terminal connected to a source terminal of an (i+1)-th FET, and an n-th FET includes a drain terminal outputting an output signal and connected to a power supply;
resistors connected to gate terminals of the second to n-th FETs of the stacked circuit;
capacitors connected to electrodes on sides opposite to the gate terminals of the respective resistors; and
first switches connected in parallel with the respective resistors.

2. The power amplifier according to claim 1, wherein each of the first switches includes an FET switch.

3. The power amplifier according to claim 1, wherein, when each of the FETs of the stacked circuit has a maximum standard voltage of Vm, a voltage applied to the drain terminal of the n-th FET of the stacked circuit is Vd, and j is an integer of 1 or more and n or less, in a case where (j−1)×Vm<Vd≤j×Vm is satisfied, (j−1) switches among the switches are closed and remaining switches are opened.

4. The power amplifier according to claim 1, wherein when load impedance as viewed from the drain terminal of the n-th FET of the stacked circuit is Z0, number of FETs performing amplification operation among the second to n-th FETs of the stacked circuit is m, m is integer of 1 or more, the FETs performing the amplification operation are numbered from 1 to m in an ascending order of the FET number in the stacked circuit, and k is an integer of 1 or more and m or less, input impedance as viewed from a source terminal of a k-th FET performing the amplification operation is set within a range from (k−0.5)/(m+1)×Z0 to (k+0.5)/(m+1)×Z0.

5. The power amplifier according to claim 4, comprising an additional capacitor connected in parallel with each of the capacitors and configured to be turned on/off by a second switch, wherein
the input impedance is set by turning on/off the second switch.

6. The power amplifier according to claim 5, wherein the second switch includes an FET switch.

7. (canceled)
